(19) United States
(12) Patent Application Publication
(10) Pub. No.: US 2024/0234471 A1
(43) Pub. Date: Jul. 11, 2024

(54) CHIP STACKING WITH AN AUXILIARY CIRCUIT CHIP ON A BACKSIDE ILLUMINATED (BSI) SURFACE OF AN IMAGE SENSOR CHIP

(71) Applicant: SEMICONDUCTOR COMPONENTS INDUSTRIES, LLC, Phoenix, AZ (US)

(72) Inventors: Tomas GEURTS, Haasrode (BE); Swarnal BORTHAKUR, Boise, ID (US)

(73) Assignee: SEMICONDUCTOR COMPONENTS INDUSTRIES, LLC, Phoenix, AZ (US)

(21) Appl. No.: 18/151,595

(22) Filed: Jan. 9, 2023

(51) Int. Cl. H01L 27/146

(52) U.S. Cl. CPC H01L 27/1464; H01L 27/14621; H01L 27/14627; H01L 27/14634; H01L 27/14636; H01L 27/14685

(57) ABSTRACT

A semiconductor device may include a primary circuit chip and an image sensor chip stacked thereon. The image sensor chip may have a backside illuminated (BSI) surface and a frontside surface opposed to the BSI surface, with the image sensor chip being disposed on the primary circuit chip with the frontside surface facing the primary circuit chip. An auxiliary chip may be disposed on the BSI surface of the image sensor chip and connected to the primary circuit chip through the image sensor chip.

### TECHNICAL FIELD

This description relates to image sensors.

### BACKGROUND

Conventional image sensors may include a pixel array used to produce color images by forming a color filter array (CFA) and associated microlenses over the pixel array. For example, complementary metal-oxide-semiconductor (CMOS) image sensors may include or utilize photodiodes, related circuitry, dielectric layers, and metal interconnects, all formed on a substrate to provide an image sensor chip.

Historically, such image sensor structures were positioned with the substrate side supported by suitable packaging, and with light incident on the image sensor through the opposed side. Consequently, the substrate side became known as the backside of the image sensor chip, while the opposed side was referred to as the frontside.

However, light incident on the frontside of the sensor is required to traverse, e.g., the related circuitry, dielectric layers, and metal interconnects that are formed on the substrate, in order to reach the pixel array. As a result, image quality may be detrimentally impacted.

In early image sensors, the backside substrate was too thick to allow light to reach the pixel array from the backside direction. However, thinning techniques and related approaches were developed to reduce a thickness of the substrate and otherwise enable illumination of the backside of the image sensor chip. In such image sensors, commonly referred to as backside illuminated (BSI) sensors, incident light is therefore not impacted by circuitry, dielectric layers, metal interconnects, or any other structural elements that might have been formed on the substrate, so that image quality may be improved.

### SUMMARY

According to one general aspect, a semiconductor device includes a primary circuit chip and an image sensor chip having a backside illuminated (BSI) surface and a frontside surface opposed to the BSI surface, the image sensor chip being disposed on the primary circuit chip with the frontside surface facing the primary circuit chip. The semiconductor device also includes an auxiliary chip disposed on the BSI surface of the image sensor chip and connected to the primary circuit chip through the image sensor chip.

According to another general aspect, a semiconductor device includes a primary circuit chip and an image sensor chip having a backside illuminated (BSI) surface and a frontside surface opposed to the BSI surface, the image sensor chip being disposed on the primary circuit chip with the frontside surface facing the primary circuit chip. The semiconductor device further includes a color filter array (CFA) and microlens array disposed on the BSI surface, an auxiliary chip disposed on the BSI surface of the image sensor chip and adjacent to the CFA and microlens array and connected to the primary circuit chip through the image sensor chip, and glass positioned above the CFA and the microlens array.

According to another general aspect, a method of making a semiconductor device includes providing an image sensor chip on a primary circuit chip, the image sensor chip having a backside illuminated (BSI) surface and a frontside surface opposed to the BSI surface, with the image sensor chip being disposed on the circuit chip with the frontside surface facing the primary circuit chip. The method further includes providing an auxiliary chip disposed on the BSI surface of the image sensor chip and connected to the primary circuit chip through the image sensor chip.

The details of one or more implementations are set forth in the accompanying drawings and the description below. Other features will be apparent from the description and drawings, and from the claims.

### BRIEF DESCRIPTION OF THE DRAWINGS

FIG. 1 is a block diagram of an image sensor chip stack.

FIG. 2 is a flowchart illustrating example operations for manufacturing the image sensor chip stack of FIG. 1.

FIG. 3 illustrates a first example implementation of the image sensor chip stack of FIG. 1 with an encapsulated wirebond.

FIG. 4 illustrates a second example implementation of the image sensor chip stack of FIG. 1 with a wirebond that is not encapsulated.

FIG. 5 illustrates a third example implementation of the image sensor chip stack of FIG. 1 with chip-scale packaging (CSP).

FIG. 6 is a top view of the example image sensor chip stack of FIG. 5.

FIG. 7 illustrates a first example operation for implementing the flowchart of FIG. 2.

FIG. 8 illustrates a second example operation for implementing the flowchart of FIG. 2.

FIG. 9 illustrates a third example operation for implementing the flowchart of FIG. 2.

FIG. 10 illustrates a fourth example operation for implementing the flowchart of FIG. 2.

FIG. 11 illustrates a fifth example operation for implementing the flowchart of FIG. 2.

FIG. 12 illustrates a sixth example operation for implementing the flowchart of FIG. 2.

FIG. 13 illustrates a seventh example operation for implementing the flowchart of FIG. 2.

FIG. 14 illustrates an example operation for implementing the flowchart of FIG. 2 to obtain the encapsulated wirebond implementation of FIG. 3.

FIG. 15 illustrates a first example operation for implementing the flowchart of FIG. 2 to obtain the unencapsulated wirebond implementation of FIG. 4.

FIG. 16 illustrates a second example operation for implementing the flowchart of FIG. 2 to obtain the unencapsulated wirebond implementation of FIG. 4.

FIG. 17 illustrates a first example operation for implementing the flowchart of FIG. 2 to obtain the CSP implementation of FIG. 5.

FIG. 18 illustrates a second example operation for implementing the flowchart of FIG. 2 to obtain the CSP implementation of FIG. 5.

FIG. 19 illustrates a third example operation for implementing the flowchart of FIG. 2 to obtain the CSP implementation of FIG. 5.

FIG. 20 illustrates a fourth example operation for implementing the flowchart of FIG. 2 to obtain the CSP implementation of FIG. 5.

### DETAILED DESCRIPTION

Image sensor chips are used in many different contexts, and may therefore have different requirements for functioning optimally in desired use case scenarios. For example, some image sensors may require only low-speed image capture of low-resolution images, while other image sensors may require high speeds and high resolutions. Moreover, resulting images captured by such image sensors may be used in many different ways, and may therefore require various types of processing.

For example, some image sensors may be included in high-end cameras, which may be designed to provide fast storage of, and access to, captured images. In other examples, image sensors may be deployed in various “Internet of things” (IoT) scenarios, where it may be necessary to analyze captured images (e.g., to identify imaged objects), transmit the captured images, and/or implement a response to a captured image.

Therefore, in order to manufacture image sensors and related circuitry in an efficient and customized manner, some aspects of image sensors and related image processing may be standardized across multiple types or classes of image sensors and/or applications. In addition, auxiliary or supplemental processing may be provided through the use of a customized chip(s) that is more specific to individual types of use case scenarios.

For example, as described in detail, below, an image sensor wafer may be bonded to a circuit wafer, such as, e.g., an Application Specific Integrated Circuit (ASIC) wafer. That is, the image sensor wafer may include many different image sensors formed thereon, while the circuit wafer includes many different circuits related to, e.g., image processing. Once bonded, the two wafers may be singulated into individual dies that each contain a chip stack that provides desired image sensing/processing functions.

Such an approach has many advantages. For example, the image sensor wafer and the circuit wafer may be the same size (e.g., diameter) as one another, so that they may be stacked in a highly efficient manner, with little or no wasted wafer surface area.

Moreover, manufacturing processes performed at the wafer level and prior to singulation (referred to herein as wafer-level processing) may be performed in a highly efficient and cost-effective manner. For example, color filter arrays (CFAs) and microlens arrays may be disposed on desired image sensors in a fast, efficient manner, prior to singulation. In other examples, circuit testing may be efficiently performed at the wafer level, and defective circuits may be discarded without incurring the expense of further processing.

Unfortunately, it may be difficult, expensive, and/or impractical to include the types of specialized auxiliary chips and related circuitry referenced above within such image sensor stacks. For example, it is possible to manufacture a third wafer (in addition to an image sensor wafer and circuit wafer) for the auxiliary circuitry, and then include the third wafer within the wafer stack for associated wafer-level processing. For example, a three-wafer stack may be formed with the primary circuit wafer, the auxiliary circuit wafer, and the image sensor wafer.

In many cases, however, the auxiliary circuitry may have a different size (e.g., may be significantly smaller) than a size of a corresponding image sensor chip and primary circuit chip. Therefore, forming such a three-wafer stack may result in wasted surface area of the auxiliary chip wafer. Additionally, it may be difficult to form desired connections in an effective manner between the image sensor chip(s) and the primary circuit chip(s), with auxiliary circuit chips being disposed therebetween.

It is also possible to provide a desired auxiliary circuit chip separately from the image sensor chip/primary circuit chip stack. For example, the chip stack and the auxiliary circuit chip may both be provided adjacent to one another on an underlying substrate, and the auxiliary circuit chip may be wired to the chip stack. In such configurations, though, there may be an unacceptable degree of latency in communications with the auxiliary circuit chip, due to the relatively large distance of the auxiliary circuit chip from the chip stack. Such latencies may be particularly unacceptable for image sensors requiring high-speed processing.

It is also possible to form auxiliary circuits on the same wafer as the primary circuits. However, such approaches lead to higher costs associated with making the combined primary/auxiliary wafer and difficulties in integrating the different types of primary/auxiliary circuits.

In order to retain the advantages of wafer-level processing of image sensor chip/circuit chip stacks, while still enabling desired types of customized image sensor processing, described techniques position an auxiliary circuit chip on a BSI surface of the image sensor chip, and connect the auxiliary circuit chip through the image sensor chip to the primary circuit chip. In other words, and as described and illustrated in detail, below, the auxiliary circuit chip may be positioned on the BSI surface of the image sensor chip so as to be adjacent to a CFA/microlens array(s) that is also positioned on the BSI surface of the image sensor chip.

Since the CFA/microlens array(s) may be provided within a surface area that is smaller than a surface area of the BSI surface of the image sensor chip, the auxiliary circuit chip may be positioned to use wafer/chip area that might otherwise be used inefficiently or wasted. Moreover, described techniques provide low-latency connections between the auxiliary circuit chip and the primary circuit chip. Using described techniques, one or more of many different types of auxiliary circuit chips may be added to a BSI surface of an image sensor chip, so that the resulting chip stack may be easily customized for use in many different use case scenarios, while ensuring that the chip stack may still be manufactured in a reliable, cost-effective manner.

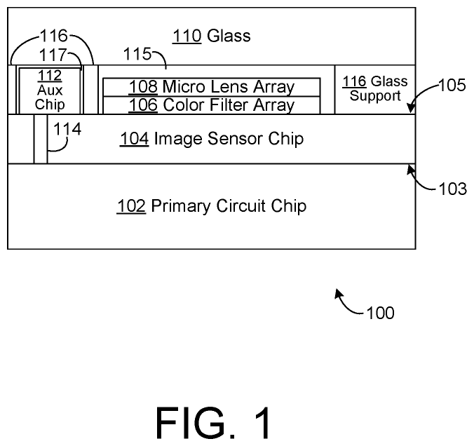

FIG. 1 is a block diagram of an image sensor chip stack 100. As referenced above, and illustrated in FIG. 1, the chip stack 100 includes a primary circuit chip 102, which may be referred to as a primary chip, a circuit chip, or a first chip. The primary circuit chip 102 may include, e.g., an ASIC chip, or an image sensor processor (ISP) chip.

An image sensor chip 104 may be disposed on the primary circuit chip. For example, the image sensor chip 104 may include a CMOS chip. As shown, a frontside 103 of the image sensor chip 104 (e.g., a bottom surface in FIG. 1) may be face-to-face with an upper surface of the primary circuit chip 102, while a BSI surface 105 of the image sensor chip 104 faces an upwards direction in FIG. 1, away from the primary circuit chip 102 and opposed to the frontside surface 103.

Thus, a CFA 106 and a microlens array 108 may be disposed on the BSI surface 105 of the image sensor chip 104 (e.g., on corresponding pixels of the image sensor chip 104, not visible in FIG. 1), as described above. Glass 110 is disposed at a top level of the chip stack 100, and provides a transparent, protective covering for underlying elements of the chip stack 100.

As further illustrated, an auxiliary circuit chip 112 (which may be referred to as an auxiliary chip, a supplemental chip, a chiplet, or a second chip) may be disposed on the BSI surface 105 of the image sensor chip 104. The auxiliary chip 112 may be connected to the primary circuit chip 102 by one or more connection(s) 114, examples of which are provided in more detail, below.

As referenced above, the auxiliary chip 112 may represent a chip designed to provide one or more of many different types of functions intended to supplement, facilitate, or customize operations of the image sensor chip 102 and/or the primary circuit chip 102. For example, the image sensor chip 104 may be capable of very fast data read outs, while the primary circuit chip 102 may not be capable of providing correspondingly fast processing of the captured image data. In such scenarios, the auxiliary chip 112 may include Dynamic Random Access Memory (DRAM), which provides fast storage of, and access to, captured image data. Consequently, image data may be captured quickly and stored using the DRAM of the auxiliary chip 112, and then the primary circuit chip 102 may access the stored image data from the auxiliary chip 112 at a speed that is manageable by the primary circuit chip 102.

In other examples, the auxiliary chip 112 may provide one or more artificial intelligence (AI) functions, which may be used to at least partially control operations of the primary circuit chip 102 with respect to image data captured by the image sensor chip 104. For example, in an IoT scenario, AI of the auxiliary chip 112 may provide an event sensing function, which determines whether an anticipated event is likely to occur, or has occurred. If so, the auxiliary chip 112 may then activate corresponding image capture functionalities of the image sensor chip 104 and the primary circuit chip 102. In this way, resources associated with operating the image sensor chip 104 and the primary circuit chip 102 may be conserved until needed.

Many other functionalities of the auxiliary chip 112 may be implemented. Moreover, although FIG. 1 illustrates only a single auxiliary chip 112, various example implementations may include two or more auxiliary chips, each customized to provide an intended function. Further, although FIG. 1 illustrates only a single primary circuit chip 102, various example implementations may include two or more primary circuit chips within the chip stack 100, each or any of which may be connected to one or more auxiliary chip(s) 112.

Further in FIG. 1, a cavity 115, e.g., an air-filled cavity or gap, may be formed above and/or around the CFA/microlens array(s) 106/108, using glass support(s) 116. In some implementations, the cavity 115 may be omitted. For example, the glass 110 may be attached to an adhesive that attaches to an intermediate layer that attaches to the CFA/microlens 106/108. In such implementations, the intermediate layer may be used to enable the microlens 108 to function in an intended manner. For example, a refractive index of the intermediate layer may be lower (e.g., 1.2 at 550 nm) than a refractive index of the microlens 108 (e.g., 1.5 at 550 nm). The refractive index of the adhesive in such embodiments may be higher, equal or lower than the intermediate layer.

In FIG. 1, a cavity 117 may be formed around the auxiliary chip 112, which may be air-filled or filled with organic material, or other suitable material. In some implementations, only a single cavity may be formed around all of the CFA/microlens array(s) 106/108 and the auxiliary chip 112.

As shown, one or more glass supports 116 may be positioned on the BSI surface 105 and surrounding the auxiliary chip 112 and the CFA/microlens array(s) 106/108. The glass supports 116 may be transparent, partially opaque, or completely opaque. The glass supports 116 may include a single material, such as an epoxy or resin, or may represent two or more materials. For example, an adhesive material may be included to ensure a secure attachment of the glass 110 within the chip stack 100.

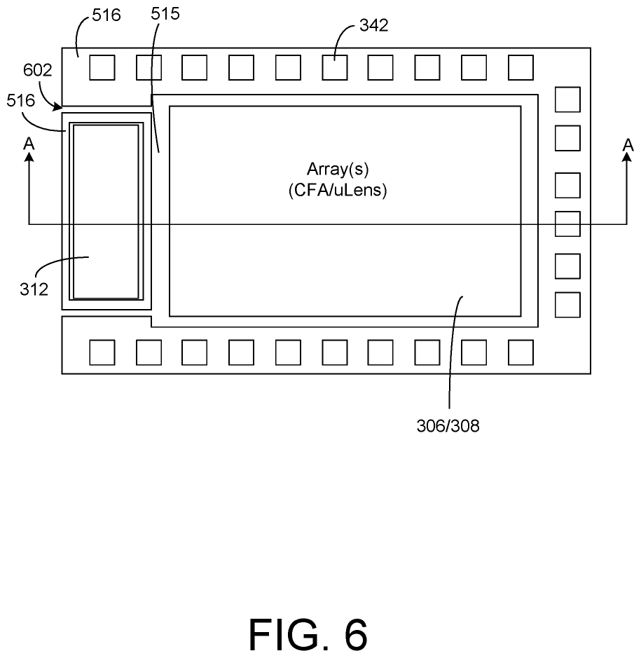

In example implementations, the glass supports 116 may extend partially or completely around a periphery of the chip stack 100. In more specific examples, it may occur that undesired air pressure builds within the cavity 115. In such cases, the glass supports 116 may be provided with pressure release openings to enable release of the undesired air pressure and thereby increase a reliability of the chip stack 100. More detailed examples of the glass supports 116 are illustrated and described below, e.g., in the top view of the example implementation of FIG. 6.

In example implementations, the glass supports 116 may be used to reduce image flare that occurs when incident light, particularly bright light, is scattered and/or reflected and causes an undesirable image artifact within captured image data. For example, the glass supports 116 may be anti-reflective, or may include an anti-reflective coating (ARC). For example, the glass supports 116 may be black to avoid undesired reflections, with a transparent or semi-transparent adhesive layer formed thereon. In other examples, the glass supports 116 may include both a transparent epoxy and a black ARC that also provides the adhesive function referenced above with respect to the glass 110.

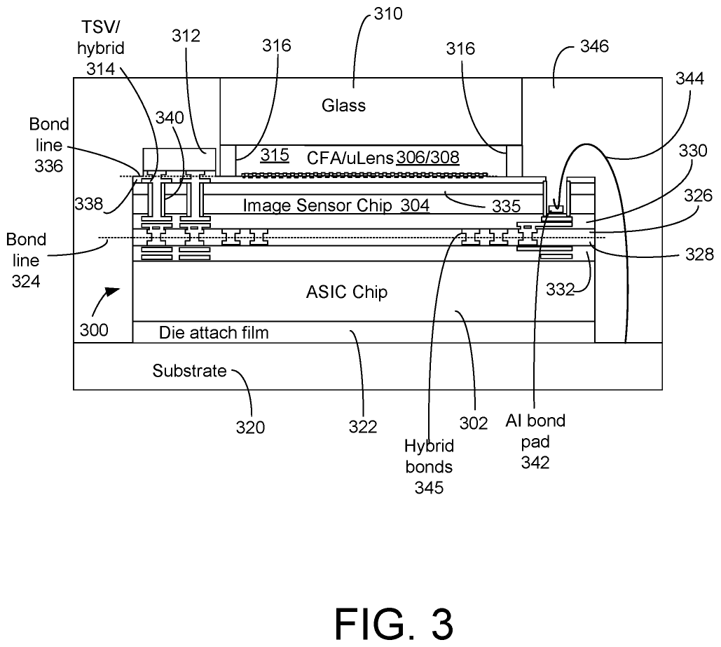

It will be appreciated that FIG. 1 is a highly simplified example intended for illustration and explanation of the preceding aspects described with respect to the chip stack 100. Many aspects, features, and components of the chip stack 100, and variations thereof, are omitted from FIG. 1 for purposes of clarity and conciseness. Moreover, neither FIG. 1, nor any of FIGS. 3-20, should be understood to be drawn to scale.

Additionally, although the term chip is used herein with reference to singulated elements of a processed wafer, it will be appreciated that each such element may include, and/or may be referred to as, a die or semiconductor die. Thus, for example, the primary circuit chip 102 may be referred to as a primary circuit die, the image sensor chip 104 may be referred to as an image sensor die, and the auxiliary chip 112 may be referred to as an auxiliary die. Other suitable terminology may be used, as well.

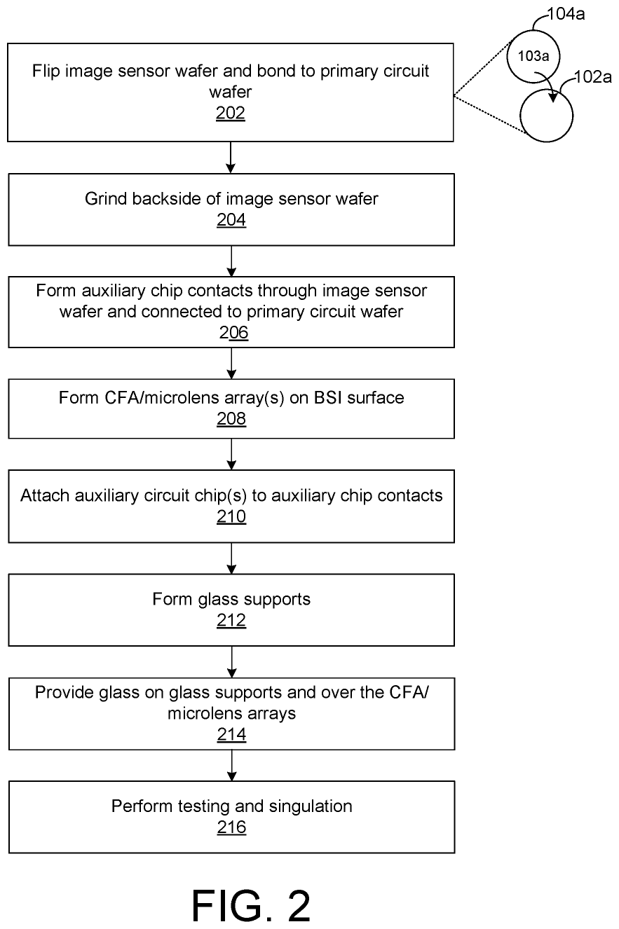

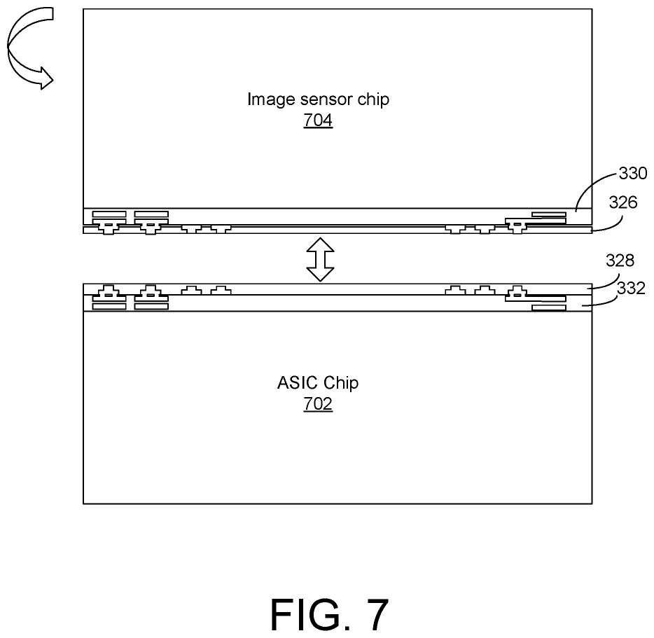

FIG. 2 is a flowchart illustrating example operations for manufacturing the image sensor chip stack of FIG. 1. More detailed examples of the operations of FIG. 2 are illustrated and described below, e.g., with respect to FIGS. 7-20.

In the example of FIG. 2, an image sensor wafer may be flipped and bonded to a primary circuit wafer (202). FIG. 2 illustrates a simplified example in which an image sensor wafer 104a processed to include large numbers of image sensors may be flipped and bonded via its frontside surface 103a to a corresponding primary circuit wafer 102a (e.g., an ASIC wafer, or an ISP wafer), on which corresponding large numbers of primary circuits have been formed.

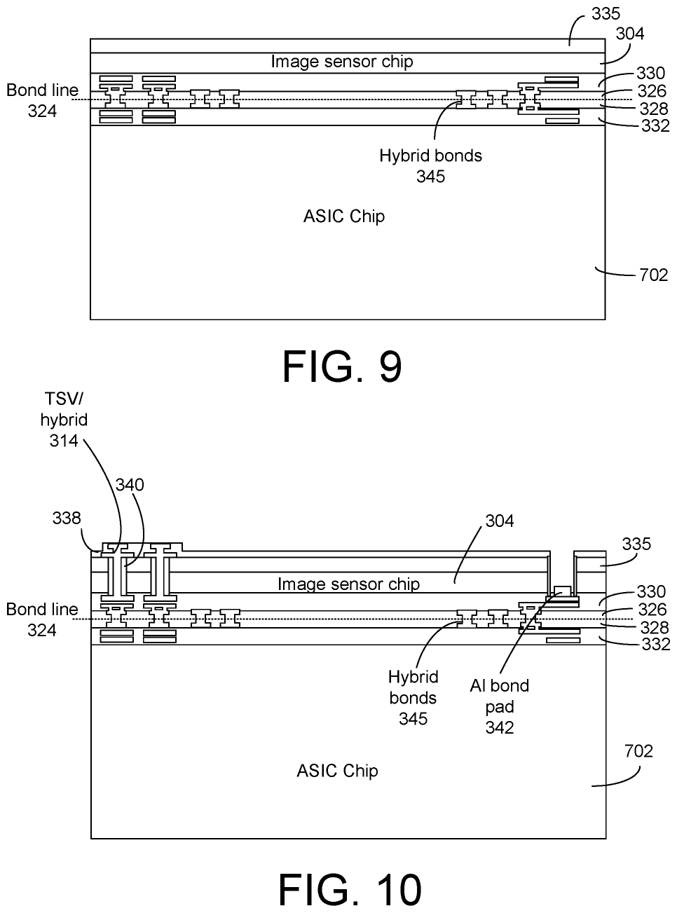

Grinding of a backside of the image sensor wafer 104a may then be performed, e.g., as shown in FIG. 9, in order to thin the image sensor wafer 104a sufficiently to enable backside illumination of the included pixels, as described above. Auxiliary chip contacts or connections may be formed through the image sensor wafer 104a to enable connections to the primary circuit wafer 102a (206).

Then, CFA/microlens arrays may be formed at appropriate locations on the BSI surface of the image sensor wafer 104a (208). Auxiliary circuit chip(s) may then be attached to the previously-established auxiliary chip contacts (210), to thereby connect the auxiliary chip(s) to the primary circuits of the primary circuit wafer 102a.

Glass supports may then be formed (212), and glass may be provided on the glass supports and over the CFA/microlens arrays 214). Die testing and singulation may be performed (216). For example, various types of testing may be performed before or after singulation.

It will be appreciated that the simplified example of FIG. 2 illustrates an example sequence of manufacturing operations, but that the various operations may occur in a different order than that shown and/or may have more or fewer operations than that shown. For example, depending on available testing and packaging options or preferences, singulation may occur prior to attaching the glass to the glass supports.

As described in more detail below, it may be preferable to utilize the illustrated sequence of forming the auxiliary chip contacts, followed by forming the CFA/microlens arrays, followed by attaching the auxiliary chips, as shown in FIG. 2. For example, the auxiliary chip(s) may be relatively large as compared to the CFA/microlens arrays, and might interfere with formation of the CFA/microlens arrays if attached prior thereto. Nonetheless, any suitable techniques may be used to manufacture the various chip stacks described herein, or similar chip stacks.

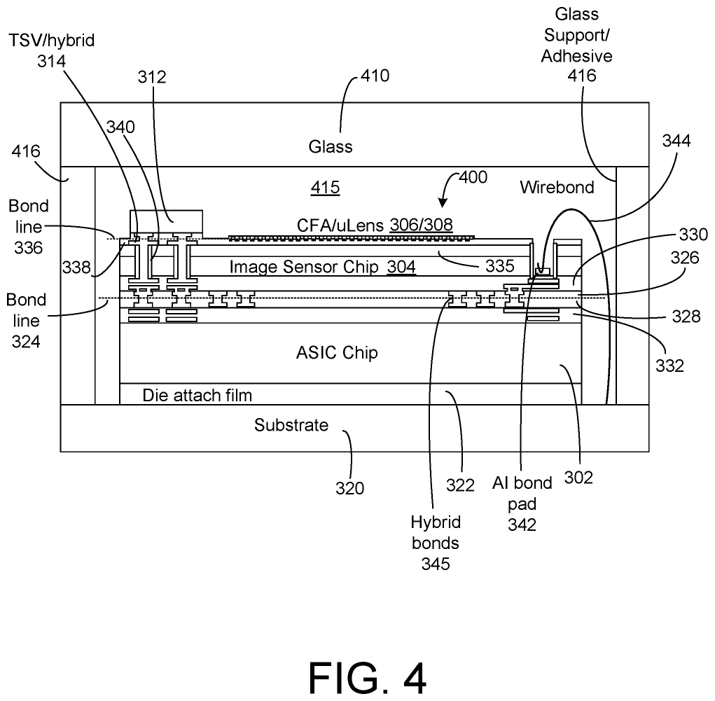

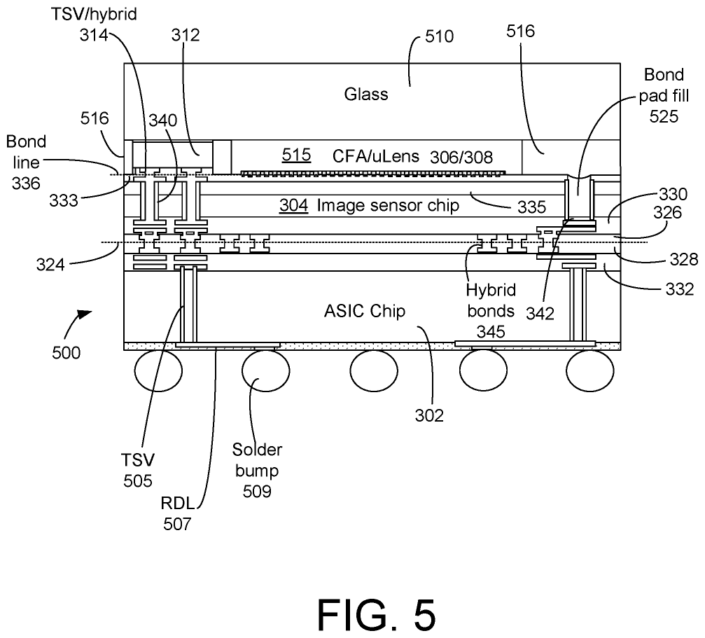

FIG. 3 illustrates a first example implementation of the image sensor chip stack of FIG. 1 with an encapsulated wirebond. FIG. 4 illustrates a second example implementation of the image sensor chip stack of FIG. 1 with a wirebond that is not encapsulated. FIG. 5 illustrates a third example implementation of the image sensor chip stack of FIG. 1 with chip-scale packaging (CSP). FIG. 6 is a top view of the example image sensor chip stack of FIG. 5.

In the examples of FIGS. 3-6, as well as in the subsequent manufacturing process flows of FIGS. 7-20, a number of common elements are included, many of which correspond to, or provide examples of, previously-discussed elements of FIG. 1. Such elements are numbered to correspond to the numbering scheme of FIG. 1, and are labelled identically where included throughout FIGS. 3-20 for the sake of conciseness and clarity.

For example, in FIG. 3, an ASIC chip 302 corresponds to the primary circuit chip 102 of FIG. 1, and has an image sensor chip 304 disposed thereon, corresponding to the image sensor chip 104 of FIG. 1. As described above, the ASIC chip 302 may be connected and configured to control various operations of the image sensor chip 304.

A CFA 306 and a microlens array 308 are disposed on a BSI surface of the image sensor chip 304, as described above. Glass 310 is supported by glass supports 316, which together define an air-filled cavity 315.

An auxiliary circuit chip 312 is disposed on the BSI surface of the image sensor chip 304. As described, the auxiliary chip 312 may represent, e.g., a DRAM chip, an AI chip, or any chip configured to provide additional or supplemental processing for the ASIC chip 302 and/or the image sensor chip 304.

Further in FIG. 3, a substrate 320 provides support for the illustrated chip stack 300, with the ASIC chip 302 being attached to the substrate 320 using a suitable die attach film 322. In addition to providing mechanical support for the chip stack 300 of FIG. 3, the substrate 320 may be used to position various other circuit elements, and may thereby be configured to enable electrical connections between the chip stack 300 of FIG. 3 and such various other circuit elements.

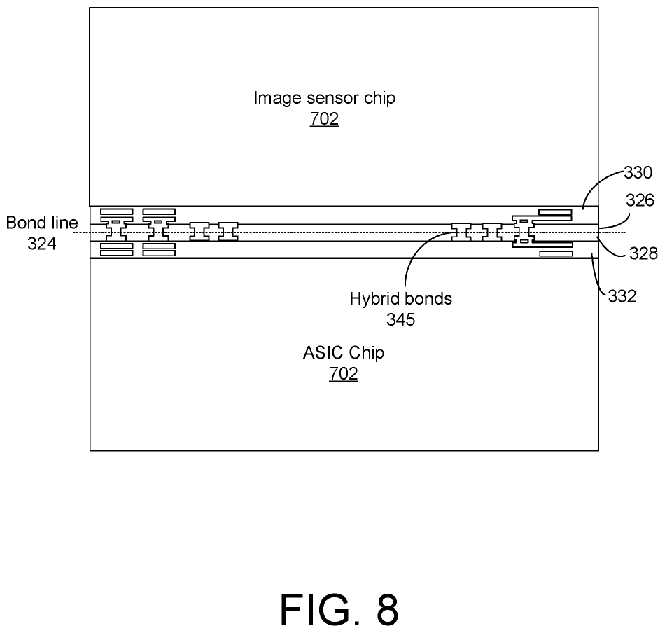

A bond line 324 defines a point of interface between the ASIC chip 302 and the image sensor chip 304, as described and illustrated in more detail, below, with respect to FIGS. 7 and 8. A dielectric layer 326 is disposed on a dielectric layer 330 on the image sensor chip 304, while a dielectric layer 328 is disposed adjacent to a dielectric layer 332 on the ASIC chip 302. For example, the dielectric layers 326-332 may be formed using any suitable dielectric materials, including, e.g., Silicon Dioxide (e.g., SiO₂) and/or Silicon Nitride.

As also illustrated, the dielectric layers 326-332 may be used to construct desired bonds between the ASIC chip 302 and the image sensor chip 304, illustrated in FIG. 3 as hybrid bonds 345. Hybrid bonding refers to bonds that combine dielectric bonds with embedded metal to form interconnections. A hybrid bond may also be referred to as a direct bond interconnect (DBI). In the example of FIG. 3, the hybrid bond(s) 345 may be implemented using copper-to-copper connections. Other types of connections, such as solder ball attach or copper pillar connections, may also be used.

A bond line 336 may define a point of interface between the image sensor chip 304 and the auxiliary chip 312. As shown, a passivation layer 335, which may include, e.g., aluminum oxide, hafnium oxide, tantalum oxide, and/or silicon dioxide, may be disposed on the image sensor chip 304, and a dielectric layer 338 may be disposed thereon.

In FIG. 3, a through-Silicon via (TSV) hybrid bond 314 provides an example of the connection(s) 114 of FIG. 1 between the auxiliary chip 312 and the ASIC chip 302, formed through the image sensor chip 304. In the example of FIG. 3, the TSV/hybrid bond 314 is formed using a sidewall passivation layer 340, which may be, e.g., SiO₂. Other types of connections may additionally or alternatively be used, some of which are referenced above.

An aluminum (Al) bondpad 342 is illustrated as having a wirebond 344 connected thereto. As referenced above, and described in more detail, below, the bondpad 342 and the wirebond 344 may be used for testing various aspects of operations of the image sensor chip 304 and/or other elements of the chip stack 300 of FIG. 3. For example, the wirebond 344 enables wafer-level testing that may be performed prior to singulation operations, so that testing may be performed in an efficient manner.

Finally in FIG. 3, molding 346 is illustrated as enclosing, together with the glass 310 and the substrate 320, an entirety of the chip stack 300. The molding 346 may be provided using any suitable epoxy or other molding material.

FIG. 4 is similar to FIG. 3, except that in the example of FIG. 4, glass supports 416 are positioned on the substrate 320. As shown, a cavity 415 thus extends around the chip stack 400, so that the wirebond 344 is not encapsulated.

FIG. 5 illustrates an example implementation with chip scale packaging. In FIG. 5, glass 510 extends across a width of the chip stack 500, and is supported by glass supports 516, over bond pad fill 525. Bond pad 342 is covered by bond pad fill 525, because the bond pad 342, in contrast to the examples of FIGS. 3 and 4, is not wired for use in the example of FIG. 5. For example, the bond pad 342 may have been used earlier in processing for wafer-level testing, and subsequently covered by bond pad fill 525.

Also in FIG. 5, a TSV 505 is illustrated as extending through the ASIC chip 302 to provide a redistribution layer (RDL) 507 that is connected to solder bump 509. In this way, heat from the auxiliary chip 312 may be transferred to the solder bump 509 and away from the image sensor chip 304.

For example, in cases where the auxiliary chip 312 provides excess heat during operation, such heat may cause negative effects on image processing operations of the image sensor 304. For example, the image sensor 304 may experience dark current that causes negative effects on captured images, and that tends to increase with increasing heat. By providing the TSV 505 with a copper connection through the RDL 507 to the solder bump 509, such heat may be effectively dispersed.

It will be appreciated that various aspects of FIGS. 3-5 may be combined, and that FIGS. 3-5 do not illustrate all possible variations of implementations of the chip stack 100 of FIG. 1. For example, FIG. 5 is not illustrated with the substrate 320 of FIGS. 3 and 4, because FIG. 5 illustrates a chip scale packaging of the chip stack 500, while FIGS. 3 and 4 are not illustrated as including the TSV 505/RDL 507/solder bumps 509 of FIG. 5. Nonetheless, in various implementations, the TSV 505/RDL 507/solder bumps 509 of FIG. 5 may also be included in implementations of the encapsulated or nonencapsulated wirebond implementations of FIGS. 3 and 4, respectively (e.g., on a bottom of the substrate 320).

FIG. 6 is an example top view of the example of FIG. 5. That is, FIG. 5 is a cross-sectional view taken along line A-A of FIG. 6.

In the example of FIG. 6, the glass supports 516 are illustrated as extending around a perimeter of the illustrated chip stack, and having one or more pressure-release gaps 602. The pressure-release gaps 602 may be configured (e.g., positioned and sized) to enable release of air pressure that may build up within the air-filled cavity 515.

For example, the air-filled cavity 515 may expand during qualification and reliability testing of the chip stack 500, and may cause the glass 510 to de-attach. By adding the pressure-release gaps 602 at an appropriate size, it is possible to release sufficient air pressure from the air-filled cavity 515, while ensuring that moisture or other contaminants do not enter the air-filled cavity 515. For example, the pressure-release gaps 602 may have a size on the order of about 1 micron. Additionally, or alternatively, holes may be formed in the glass 510 to serve the same function.

In the example of FIGS. 5 and 6, the glass supports 516 (and the glass 510) may be transparent, so that the bond pads 342 are visible in the top view of FIG. 6. In other example implementations, as referenced above, the glass supports 516 may be opaque, e.g., black, in order to provide anti-reflective properties that facilitate image capture by the image sensor chip 304.

In various examples, the glass supports 516 may have adhesive properties to adhere to the glass 510, while in other example, the glass supports 516 may include or be attached to a separate adhesive material. For example, the glass supports 516 may be opaque, e.g., black, while an additional, included adhesive layer for adhering the glass 510 to the glass supports 516 may be transparent or semi-transparent. For example, the glass supports 516 may be formed of a suitable carbon blackened epoxy.

Also, in the example of FIG. 6, the glass supports 516 are illustrated as rectangular. In various implementations, however, the glass supports 516 may be any suitable shape.

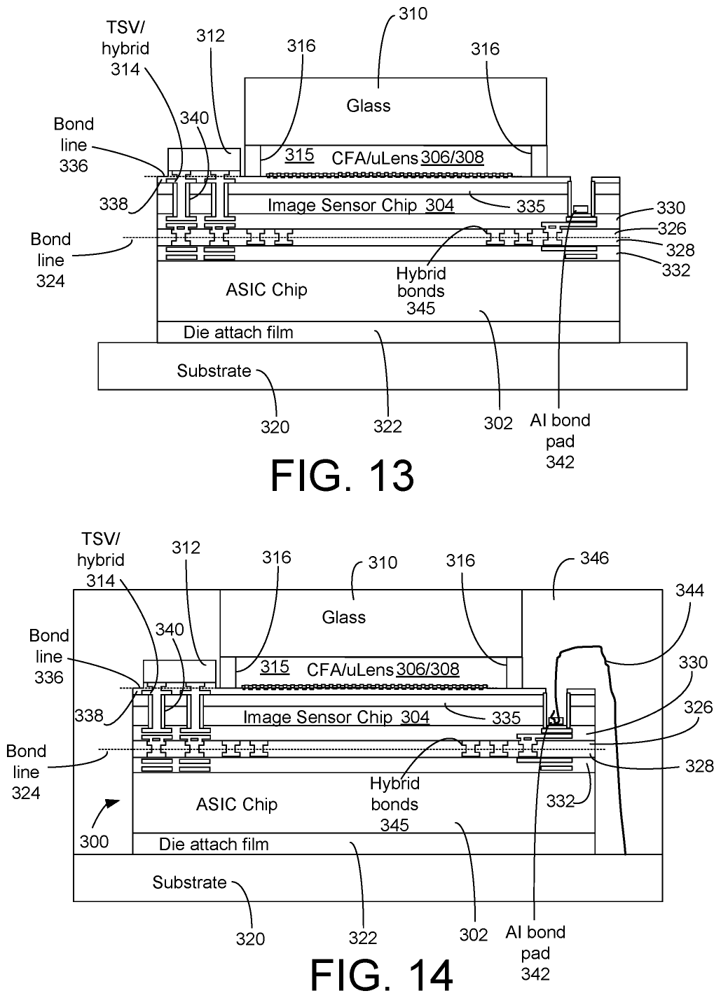

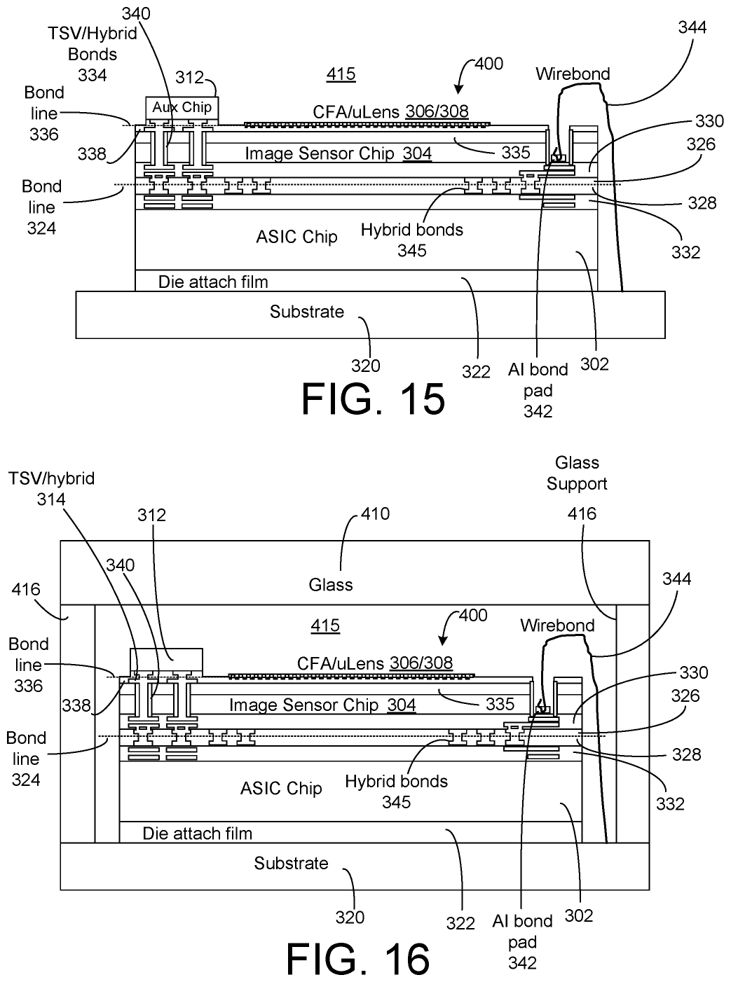

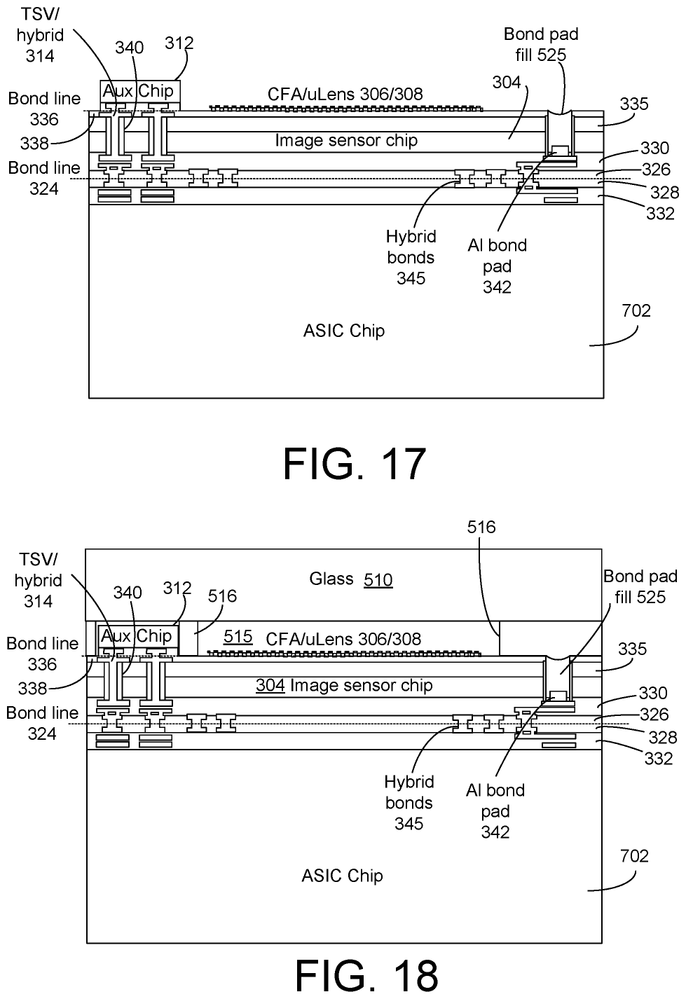

FIGS. 7-20 illustrate example operation for implementing the flowchart of FIG. 2 to manufacture one or more of the example implementations of FIGS. 1 and 3-6. As described in detail, below, FIGS. 7-12 illustrate initial operations that may be performed for any or all of the implementations of FIGS. 3-6. FIGS. 13 and 14 illustrate operations that may be performed to provide the implementation of FIG. 3. FIGS. 15-16 illustrate operations that may be performed to provide the implementation of FIG. 4. FIGS. 17-20 illustrate operations that may be performed to provide the implementation of FIGS. 5 and 6.

In the example of FIG. 7, an ASIC chip 702 has an image sensor chip 704 flip-mounted and bonded thereto, as further shown in FIG. 8. That is, as described above, e.g., with respect to FIG. 2, a compatible image sensor wafer and ASIC wafer may be flip-mounted and bonded, using, e.g., hybrid bonds 345 formed using the various dielectric layers 326-332, as described above.

In FIG. 9, the image sensor chip 704 may be thinned to form the thinned image sensor chip 304, and the passivation layer 335 may be provided thereon. For example, various known thinning techniques may be used, such as coarse grinding, fine grinding, wet etching, and/or combinations thereof. Various types of BSI processing may also be performed at this stage.

In FIG. 10, TSV/hybrid connections 314 may be provided, as described above, including, e.g., copper contacts and sidewalls 340. As also referenced above, dielectric layer 338 may be provided on the passivation layer 335 and on the TSV/hybrid connections 314. The Al bond pad 342 (e.g., probe pad, or wirebond pad) may also be formed.

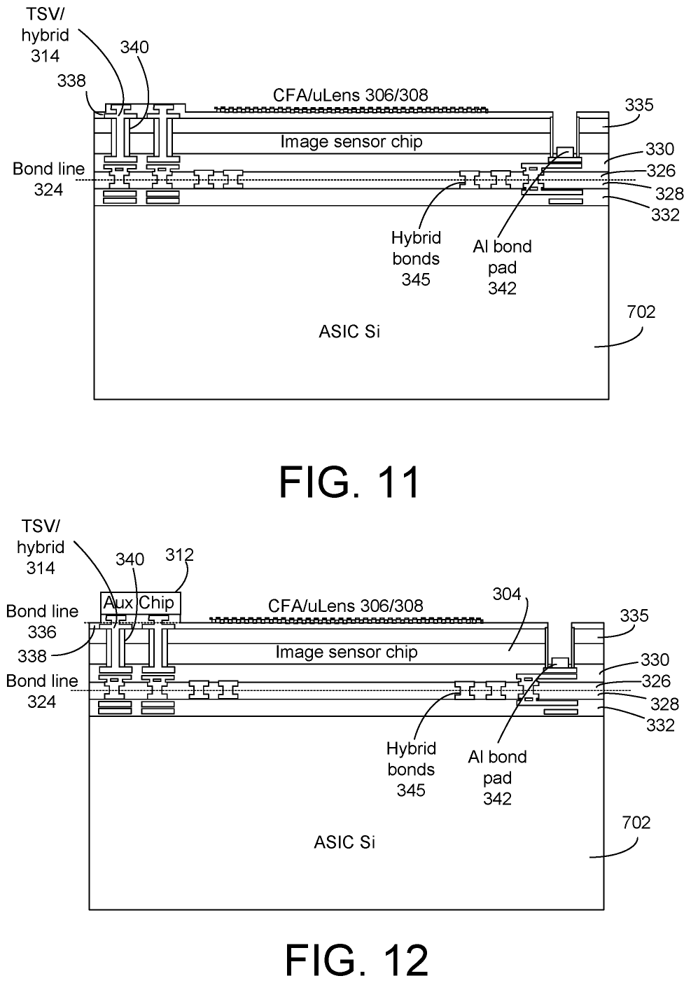

In FIG. 11, the CFA/microlens arrays 306/308 are added, and in FIG. 12, the auxiliary chip 312 is added. For example, the auxiliary chip 312 may have a height of about 25-50 microns. In some examples, the height of the auxiliary chip 312 may be determined based on corresponding heights of glass supports to be added later, e.g., to be a similar height as the glass supports 316 of the encapsulate wirebond examples of FIGS. 3, 13, and 14, or as the glass supports 516 of the chip scale packaging implementation of FIGS. 5, 6, and 17-20.

In more detail, example implementations may provide the CFA/microlens arrays 306/308 prior to adding the auxiliary chip 312, because, e.g., the CFA/microlens arrays 306/308 may be added using spin-on processing. If the auxiliary chip 312 is added prior to such spin-on processing, streaking in the applied photoresist of the spin-on processing may occur, which may result in defects in the CFA/microlens arrays 306/308.

On the other hand, the spin-processing used to add the CFA/microlens arrays 306/308 may itself cause damage (e.g., contamination) to Cu hybrid bonds of the TSV/hybrid bond connections 314. The passivation layer 338 (e.g., SiO₂) prevent such damage, but must then be removed after the CFA/microlens arrays 306/308 (and the bond pad 342) are provided. For example, the passivation layer may be etched to expose underlying Cu pads, and cleaned with an appropriate solvent, acid, or plasma. Then, pick-n-place operations may be used to place the auxiliary chip 312 (i.e., to place all auxiliary chips across the BSI surface of the image sensor wafer, as shown by the image sensor wafer 204a in FIG. 2).

In FIG. 13, to obtain the example implementation of FIG. 3, grinding of the ASIC chip 702 may be performed to obtain the thinned ASIC chip 302, as shown. Then, following singulation, the chip stack may be mounted to the substrate 320 using the die attach film 322. Glass supports 316 and any associated adhesives may be added, as well.

In FIG. 14, the wirebond 344 may be added. Then, encapsulation may be performed to add molding 346. In this way, the encapsulated wirebond embodiment of FIG. 3 may be obtained.

To obtain the unencapsulated wirebond embodiment of FIG. 4, as shown in FIGS. 15 and 16, the ASIC chip 702 may be thinned as described above with respect to FIG. 13. Following singulation, the chip stack may be mounted to the substrate 320 using the die attach film 322, and the wirebond 344 may be added.

In FIG. 16, glass supports 416 are added by mounting onto the substrate 320. Then, glass 410 is attached to the glass supports 416 using the included adhesive, as described above, to thereby obtain the unencapsulated wirebond embodiment of FIG. 4.

To obtain the chip scale packaging of FIGS. 5 and 6, as shown in FIG. 17, beginning from the stage shown in FIG. 12, the bond pad fill 525, e.g., an organic spin-coated material, may be added. As shown, the ASIC chip 702 is not yet thinned.

In FIG. 18, glass 510 is attached to glass supports 516. For example, a 50 um thick black dry film lamination may be used that includes an additional dispensed adhesive layer. There may be a gap between the glass supports 516 and the auxiliary chip 312, or the space may be filled with a suitable material, e.g., an organic material.

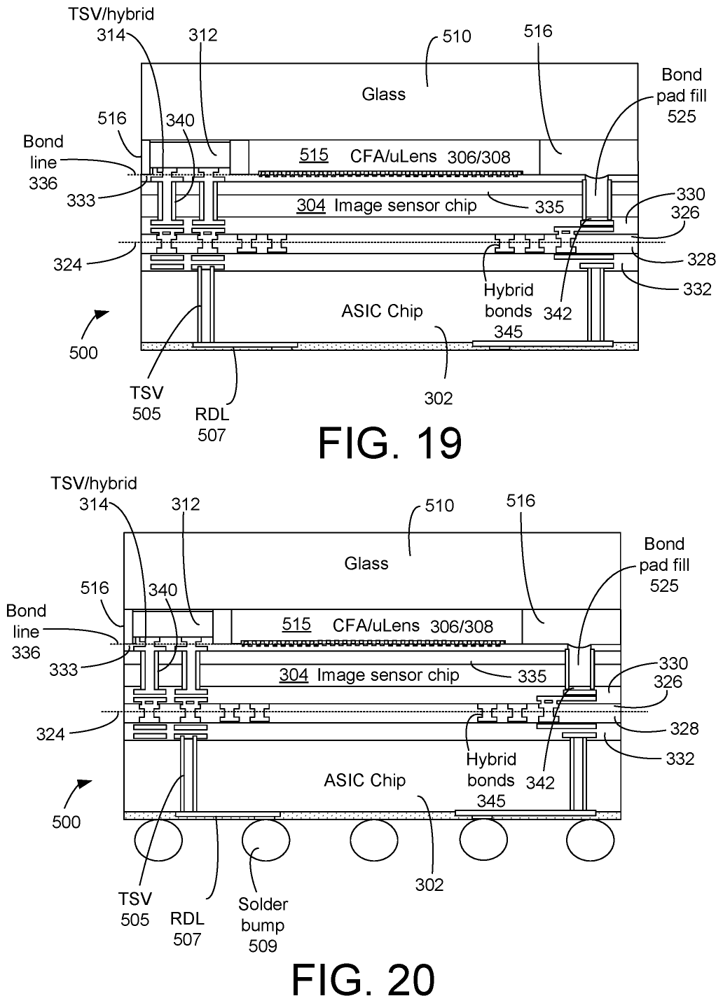

FIG. 19 illustrates that the ASIC chip 702 may be thinned to obtain the ASIC chip 302. TSV 505 and RDL 507 may then be added. Finally, in FIG. 20, the solder bumps 509 may be added, and singulation may be performed.

As described herein, it is desirable to be able to combine a chiplet (e.g., DRAM or AI die) with an image sensor/ASIC chip stack. However, as referenced above, since chiplet AI dies are typically much smaller than the image sensor/ASIC die stack, wafer-to-wafer stacking is unsuitable because of large wasted area on the chiplet die. As also referenced, connecting a DRAM or AI die, or other auxiliary chip, to an underlying substrate is also not desirable, because of latency issues resulting from the distance between the ASIC and the auxiliary chip (e.g., chiplet).

Described techniques provide a die-to-wafer or die-to-die solution in which, e.g., a chiplet is stacked on the BSI side of the image sensor/ASIC chip stack, with connections directly into the ASIC chip. Described implementations provide for both CSP and wirebond packaging options, while reducing/eliminating issues related to flare, heat dissipation, and/or pressure release.

Described techniques provide a die-to-wafer solution in which one or more auxiliary chips may be placed on a BSI surface of an image sensor/ASIC stack during wafer processing, and/or after die singulation occurs. Each resulting chip stack may therefore have one or more auxiliary chips, e.g., two or more DRAM chips, two or more AI chips, or a DRAM and an AI chip. For example, multiple auxiliary chips may be placed on a BSI surface of an image sensor chip, because the auxiliary chip may require, e.g., only 10% of the BSI surface.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments.

What is claimed is:

1. A semiconductor device, comprising:
a primary circuit chip;
an image sensor chip having a backside illuminated (BSI) surface and a frontside surface opposed to the BSI surface, the image sensor chip being disposed on the primary circuit chip with the frontside surface facing the primary circuit chip; and
an auxiliary chip disposed on the BSI surface of the image sensor chip and connected to the primary circuit chip through the image sensor chip.

2. The semiconductor device of claim 1, further comprising:
a color filter array (CFA) and microlens array disposed on the BSI surface adjacent to the auxiliary chip.

3. The semiconductor device of claim 2, further comprising:
at least one glass support disposed on the BSI surface and adjacent to the auxiliary chip; and
glass disposed on the at least one glass support and positioned above the CFA array and the microlens array, and defining a cavity between the glass, the at least one glass support, and the BSI surface, with the CFA and the microlens array disposed within the cavity.

4. The semiconductor device of claim 3, wherein the at least one glass support is anti-reflective.

5. The semiconductor device of claim 3, wherein the at least one glass support extends around a perimeter of the BSI with at least one pressure release opening formed therein and sized to release air pressure from the cavity while preventing moisture from entering the cavity.

6. The semiconductor device of claim 3, further comprising:
a substrate with the primary circuit chip disposed thereon;
mold disposed on the substrate and at least partially encapsulating the primary circuit chip, the image sensor chip, the auxiliary chip, the at least one glass support, and the glass.

7. The semiconductor device of claim 1, further comprising:
a substrate with the primary circuit chip disposed thereon;
at least one glass support disposed on the substrate; and
glass disposed on the at least one glass support and defining a cavity between the glass, the at least one glass support, and the BSI surface.

8. The semiconductor device of claim 1, further comprising:
at least one solder bump with the primary circuit chip disposed thereon;
a through Silicon via (TSV) with a redistribution layer (RDL) formed therein that extends through the primary circuit chip and connects the auxiliary chip to the at least one solder bump.

9. The semiconductor device of claim 1, wherein the auxiliary chip is connected to the primary circuit chip through the image sensor chip using a through Silicon via (TSV) with a hybrid bond.

10. The semiconductor device of claim 1, wherein the auxiliary chip includes at least one of a dynamic random access memory (DRAM) chip or an artificial intelligence (AI) chip.

11. A semiconductor device, comprising:
a primary circuit chip;
an image sensor chip having a backside illuminated (BSI) surface and a frontside surface opposed to the BSI surface, the image sensor chip being disposed on the primary circuit chip with the frontside surface facing the primary circuit chip;
a color filter array (CFA) and microlens array disposed on the BSI surface;
an auxiliary chip disposed on the BSI surface of the image sensor chip and adjacent to the CFA and microlens array and connected to the primary circuit chip through the image sensor chip; and
glass positioned above the CFA and the microlens array.

12. The semiconductor device of claim 11, further comprising:
at least one glass support disposed on the BSI surface and adjacent to the auxiliary chip, with the glass disposed thereon.

13. The semiconductor device of claim 11, further comprising:
a substrate with the primary circuit chip disposed thereon;
at least one glass support disposed on the substrate, with the glass disposed on the at least one glass support and defining a cavity between the glass, the at least one glass support, and the BSI surface.

14. The semiconductor device of claim 11, further comprising:
at least one solder bump with the primary circuit chip disposed thereon;
a through Silicon via (TSV) with a redistribution layer (RDL) formed therein that extends through the primary circuit chip and connects the auxiliary chip to the at least one solder bump.

15. The semiconductor device of claim 11, wherein the auxiliary chip is connected to the primary circuit chip through the image sensor chip using a through Silicon via (TSV) with a hybrid bond.

16. A method of making a semiconductor device, comprising:
providing an image sensor chip on a primary circuit chip, the image sensor chip having a backside illuminated (BSI) surface and a frontside surface opposed to the BSI surface, with the image sensor chip being disposed on the circuit chip with the frontside surface facing the primary circuit chip; and
providing an auxiliary chip disposed on the BSI surface of the image sensor chip and connected to the primary circuit chip through the image sensor chip.

17. The method of claim 16, further comprising:
providing an image sensor wafer including the image sensor chip on a primary circuit wafer including the primary circuit chip, to thereby obtain a wafer stack; and
singulating the wafer stack to obtain a chip stack including the image sensor chip on the primary circuit chip.

18. The method of claim 17, further comprising:
providing the auxiliary chip on the image sensor chip prior to the singulating.

19. The method of claim 17, further comprising:
providing the auxiliary chip on the image sensor chip subsequent to the singulating.

20. The method of claim 16, further comprising:
providing contacts for the auxiliary chip on the BSI surface;
passivating the contacts with a passivation layer;
providing a color filter array (CFA) and microlens array on the BSI surface;
opening the passivation layer to expose the contacts; and
providing the auxiliary chip on the BSI surface and connected to the contacts.
